(19) United States
(12) Patent Application Publication
(10) Pub. No.: US 2020/0321524 A1
(43) Pub. Date: Oct. 8, 2020

(54) DEVICE FOR FABRICATING DISPLAY PANEL AND FABRICATING METHOD OF DISPLAY PANEL

(71) Applicant: Samsung Display Co., Ltd., Yongin-si (KR)

(72) Inventors: Tae Hyung HWANG, Seoul (KR); Donchan CHO, Seongnam-si (KR)

(21) Appl. No.: 16/797,659

(22) Filed: Feb. 21, 2020

(30) Foreign Application Priority Data
Apr. 4, 2019 (KR) 10-2019-0039606

(51) Int. Cl. H01L 51/00; B41M 5/00; H01L 51/56

(52) U.S. Cl. CPC H01L 51/0005; H01L 51/56; B41M 5/0047

(57) ABSTRACT

In a device for fabricating a display panel, the device includes: an inkjet printer including a plurality of nozzles configured to discharge an ink to effective areas of the display panel for each of a plurality of scan times; a discharge amount detection sensor configured to detect ink discharge amounts corresponding to the plurality of nozzles, respectively; and a controller configured to: generate a plurality of ink distributions based on shift values of the plurality of nozzles for the effective areas at each of the scan times and the ink discharge amounts; select a first ink distribution discharging the ink to a first effective area during a first scan time; and select a second ink distribution discharging the ink to a second effective area based on the first ink distribution during a second scan time after the first scan time.

### CROSS-REFERENCE TO RELATED APPLICATION

This application claims priority to and the benefit of Korean Patent Application No. 10-2019-0039606 filed on Apr. 4, 2019, in the Korean Intellectual Property Office, the disclosures of which are incorporated by reference herein in their entireties.

### BACKGROUND

Aspects of some example embodiments of the inventive concept described herein relate to a device for fabricating a display panel and a method of fabricating a display panel.

A display panel may be classified as a transmissive display panel that selectively transmits a source light generated from a light source, and a light-emitting display panel which generates a source light in the display panel itself. The display panel may include different kinds of color control layers depending on the pixels to generate a color image. The color control layer may transmit a source light belonging to a given wavelength range or may convert a color of the source light. Some color control layers may change a characteristic of a source light without changing a color of the source light.

The above information disclosed in this Background section is only for enhancement of understanding of the background and therefore the information discussed in this Background section does not necessarily constitute prior art.

### SUMMARY

Aspects of some example embodiments of the inventive concept described herein relate to a device for fabricating a display panel and a method of fabricating a display panel.

Some example embodiments of the inventive concept may include a device for fabricating a display panel that may have a relatively improved uniformity of pixels and a method of fabricating a display panel.

Some example embodiments of the inventive concept may include a device for fabricating a display panel for reducing the number of operations for securing uniformity of pixels and a method of fabricating a display panel.

According to some example embodiments, a device for fabricating a display panel includes an inkjet printer, a discharge amount detection sensor, and controller. The inkjet printer includes a plurality of nozzles configured to discharge an ink to effective areas of a display panel for each of scan times. The discharge amount detection sensor is configured to detect ink discharge amounts corresponding to the plurality of nozzles. The controller is configured to generate a plurality of ink distributions based on shift values of the plurality of nozzles for the effective areas at each of the scan times and the ink discharge amounts, select a first ink distribution discharging the ink to a first effective area during a first scan time, and select a second ink distribution discharging the ink to a second effective area based on the first ink distribution during a second scan time after the first scan time.

According to some example embodiments, the controller may be configured to generate a plurality of summed distributions generated by summing the first ink distribution and each of the plurality of ink distributions and may be configured to select an ink distribution corresponding to a summed distribution having the smallest standard deviation among the plurality of summed distributions as the second ink distribution.

According to some example embodiments, the second effective area may be shifted from the first effective area based on a change in the second ink distribution with regard to the first ink distribution.

According to some example embodiments, the number of the plurality of ink distributions may depend on the number of the plurality of nozzles.

According to some example embodiments, the controller may be configured to arrange the ink discharge amounts to correspond to an arrangement order of the plurality of nozzles and may cyclically shift the arranged ink discharge amounts based on the arrangement order to generate the plurality of ink distributions.

According to some example embodiments, the controller may be configured to select a third ink distribution discharging the ink to a third effective area based on the first and second ink distributions during a third scan time after the second scan time.

According to some example embodiments, the plurality of nozzles may move along a first direction during the first and second scan times and each of the plurality of nozzles may be arranged in a second direction intersecting with the first direction.

According to some example embodiments, the plurality of nozzles may be on the first effective area based on the first ink distribution during the first scan time and may be shifted to the second direction to be on the second effective area based on the second ink distribution.

According to some example embodiments, the first and second effective areas may be overlapped with each other to form an overlapping area, which includes first and second pixel areas. A first nozzle of the plurality of nozzles may be configured to discharge the ink in the first pixel area based on the first ink distribution during the first scan time, a second nozzle of the plurality of nozzles may be configured to discharge the ink in the second pixel area based on the first ink distribution during the first scan time, a third nozzle of the plurality of nozzles may be configured to discharge the ink in the first pixel area based on the second ink distribution during the second scan time, and a fourth nozzle of the plurality of nozzles may be configured to discharge the ink to the second pixel area based on the second ink distribution during the second scan time.

According to some example embodiments, a difference between a first thickness of the ink accumulated in the first pixel area and a second thickness of the ink accumulated in the second pixel area may be smaller than a reference thickness.

According to some example embodiments, the inkjet printer may be configured to discharge the ink to the first effective area based on the first ink distribution during the first scan time, may discharge the ink to the second effective area based on the second ink distribution during the second scan time, and may be configured to discharge the ink to a third effective area, which does not overlap with the second effective area and overlap with the first effective area, based on the second ink distribution during a third scan time after the second scan time.

According to some example embodiments, the controller may be configured to select the first and second ink distributions during a reference time before the first scan time. The reference time may be shorter than 30 seconds.

According to some example embodiments, a device for fabricating a display panel includes an inkjet printer, a discharge detection sensor, and a controller. The inkjet printer includes a plurality of nozzles which are configured to discharge an ink to a first substrate during a first printing time and then discharge the ink to a second substrate during a second printing time which includes a plurality of scan times. The discharge amount detection sensor is configured to detect ink discharge amounts corresponding to the plurality of nozzles, respectively. The controller is configured to calculate a combination of ink distributions in which the inkjet printer discharges the ink to the second substrate for each of the plurality of scan times based on the ink discharge amounts and shift values of the plurality of nozzles for effective areas of the second substrate within a reference time for replacing the first substrate with the second substrate between the first printing time and the second printing time.

According to some example embodiments, the controller may be configured to select a first ink distribution corresponding to an initial scan time of the plurality of scan times and may be configured to calculate the combination based on the first ink distribution.

According to some example embodiments, the controller may be configured to calculate the ink distributions corresponding to the number of the plurality of nozzles based on the ink discharge amounts and the shift values, and may be configured to determine any one of the ink distributions as the first ink distribution.

According to some example embodiments, the controller may be configured to calculate the ink distributions corresponding to the number of nozzles based on the ink discharge amounts and the shift values, and may be configured to select an ink distribution having the smallest standard deviation when each of the ink distributions and the first ink distribution are summed up, to determine the combination.

According to some example embodiments, a method of fabricating a display panel includes detecting ink discharge amounts corresponding to a plurality of nozzles, respectively, forming a plurality of ink distributions corresponding to shift values of the plurality of nozzles based on the ink discharge amounts, selecting a first ink distribution of the plurality of ink distributions, selecting a second ink distribution corresponding to a result having the smallest standard deviation among results obtained by summing the first ink distribution with the plurality of ink distributions, discharging the ink to a first area of a substrate based on the first ink distribution, and discharging the ink to a second area of the substrate, which is at least partially overlapped with the first area, based on the second ink distribution.

According to some example embodiments, the method of fabricating the display panel may further include selecting a third ink distribution corresponding to a result having the smallest standard deviation among results obtained by summing the first and second ink distributions with the plurality of ink distributions, and discharging the ink to a third area, which is at least partially overlapped with the first area or the second area, based on the third ink distribution.

According to some example embodiments, the first ink distribution and the second ink distribution may be selected within a reference time. After the reference time, the ink may be discharged to the first and second areas.

### BRIEF DESCRIPTION OF THE FIGURES

The above and other aspects and features of the inventive concept will become more apparent by describing in more detail aspects of some example embodiments thereof with reference to the accompanying drawings.

FIG. 1 is a block diagram of an apparatus for fabricating a display panel according to some example embodiments of the inventive concept.

FIG. 2 is an example block diagram of a controller of FIG. 1.

FIG. 3 is an example view of a process in which an inkjet printer of FIG. 1 performs a printing operation on a substrate.

FIG. 4 is an example cross-sectional view of a pixel of FIG. 3.

FIG. 5 is a view illustrating a process for calculating optimal nozzle positions for each of a plurality of scan times.

FIG. 6 is a view illustrating a process for calculating a combination of optimal nozzle positions according to some example embodiments of the inventive concept.

FIG. 7 is an example timing chart of a method of fabricating a display panel using an apparatus for fabricating the display panel of FIG. 1.

FIG. 8 is an example view illustrating a process in which an inkjet printer of FIG. 1 performs a printing process on a substrate.

FIG. 9 is a graph illustrating non-uniformity depending on the number of scans of nozzles.

FIG. 10 is an example prospective view of a display panel fabricated according to some example embodiments of the inventive concept.

### DETAILED DESCRIPTION

While the inventive concept is susceptible to various modifications and alternative forms, some example embodiments thereof are shown by way of examples in the drawings and will herein be described in more detail. It should be understood, however, that there is no intent to limit the inventive concept to the particular forms disclosed, but on the contrary, the inventive concept is to cover all modifications, equivalents, and alternatives falling within the spirit and scope of the inventive concept.

Similar reference characters may be used for similar elements in describing drawings. In the accompanying drawings, the measure of structures may be illustrated as being enlarged or reduced for clarity of embodiments of the inventive concept. Although the terms “first”, “second”, etc. may be used herein in reference to various components, such components should not be construed as being limited by these terms. These terms are only used to distinguish one element from the other. For example, “a first user device” and “a second user device” indicate different user devices. For example, without departing the scope of the present disclosure, a first element may be referred to as a second element, and similarly, a second element may be referred to as a first element. The articles “a,” “an,” and “the” are singular in that they have a single referent, however, the use of the singular form in the present document should not preclude the presence of more than one referent.

It will be further understood that the terms “comprises,” “comprising,” “includes,” and/or “including,” when used herein, specify the presence of stated features, items, steps, operations, elements, and/or components, but do not preclude the presence or addition of one or more other features, items, steps, operations, elements, components, and/or groups thereof.

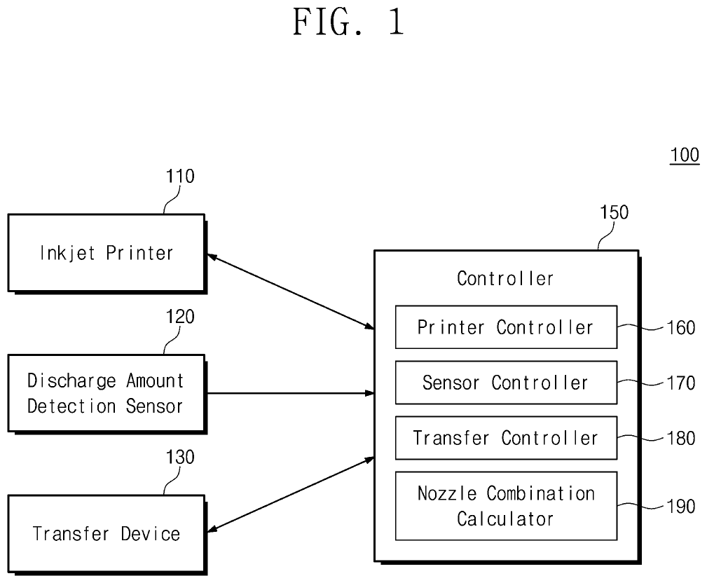

FIG. 1 is a block diagram of an apparatus for fabricating a display panel according to some example embodiments of the inventive concept. The apparatus 100 for fabricating the display panel may be configured to discharge an ink including a color composition utilized for pixels of a display panel. Referring of FIG. 1, the apparatus 100 for fabricating the display panel may include an inkjet printer 110, a discharge amount detection sensor 120, a transfer device 130, and a controller 150.

The inkjet printer 110 may discharge the ink to an effective area of the substrate. Here, the substrate may be included in the display panel, and the effective area may include pixel areas to which the inkjet printer discharges the ink. The inkjet printer 110 may discharge the ink to the pixel areas in an inkjet manner. To this end, the inkjet printer 110 may include a plurality of nozzles. The plurality of nozzles may eject the ink while scanning the effective area.

The color composition included in the ink may include a solvent and a solid matter distributed in the solvent. According to some example embodiments, the solvent may include, but is not limited to, at least one of ketones such as acetone and methyl ethyl ketone, acetic acid esters such as ethyl acetate and butyl acetate, carvitols such as cellosolve and butyl carbitol, aromatic hydrocarbons such as toluene and xylene, and amide-based solvents such as dimethylformamide and dimethylacetamide. The solid matter may include a base resin and a quantum dot. The base resin may include epoxy-based polymers and/or monomers. The color composition may further include scattering particles.

The ink ejected to each of the pixel areas may be dried in a vacuum state. Then, a uniformly dried color control layer may be formed through a baking process. According to some example embodiments, the color control layer may transmit a source light belonging to a given wavelength range or may convert a color of the source light. According to some example embodiments, the color control layer may change a characteristic of an incident light. A change in the characteristic of the light may depend on a thickness of the color control layer.

According to some example embodiments, an amount of ink provided to each of the plurality of pixel areas may be uniform throughout the entire display panel for uniformity of the characteristic change of the light. Meanwhile, due to a difference in the characteristics of each of the plurality of nozzles (e.g., such as a tolerance), the ink discharge amount discharged per unit time may not be uniform for each of the nozzles. When each of the plurality of nozzles corresponds to each of the pixel areas, respectively, and the nozzle discharges the ink to the corresponding pixel area, thicknesses of the color control layers of pixels may be different from each other due to differences between the discharge amounts of the nozzles. As a result, characteristics of each of the pixel areas may be not uniform.

The inkjet printer 110 may repeatedly discharge the ink to the substrate for a plurality of scan times. That is, the inkjet printer 110 may discharge the ink to the pixel areas several times such that each color control layer has a thickness in a reference range. However, when each of the plurality of nozzles discharges the ink to the designated pixel area, the thickness difference between the pixel areas may gradually increase as the ink is cumulatively added. To this end, the inkjet printer 110 may change the nozzles that discharge the ink to each of the pixel areas per scan time under the control of the controller 150. A more detailed description thereof will be described later.

The discharge amount detection sensor 120 may detect the ink discharge amounts per discharge time corresponding to the plurality of nozzles of the inkjet printer 110. Here, the discharge time may be a time at which each of the plurality of nozzles discharges the ink to one pixel area for one scan time. The ink discharge amount may be defined as a volume of the ink, which is discharged from each of the plurality of nozzles per discharge time. The ink discharge amounts corresponding to the plurality of nozzles may be different from each other depending on the characteristic difference of each of the plurality of nozzles.

The discharge amount detection sensor 120 may detect the ink discharge amounts before the inkjet printer 110 discharges the ink. A position combination of the nozzles may be calculated using each of the ink discharge amounts corresponding to each of the plurality of nozzles such that a total amount of the ink to be discharged to each of the plurality of pixel areas may be equalized. As the discharge amount detection sensor 120 may detect the ink discharge amounts before the inkjet printer 110 performs a printing operation, calculation of the position combination may also be performed before performing the printing operation.

The ink discharge amount may vary depending on use of the nozzle. Therefore, the discharge amount detection sensor 120 may detect the ink discharge amounts in real time before performing the printing operation on each of a plurality of substrates. Thus, a state change of each of the nozzles may be continuously considered in the printing operation.

The discharge amount detection sensor 120 may detect the ink discharge amounts in various ways. For example, the discharge amount detection sensor 120 may include a laser sensor. The laser sensor may output a laser beam and may detect the laser beam reflected on the ink. The laser sensor may calculate the ink discharge amount based on a time when the reflected laser beam is detected. However, the inventive concept is not limited thereto, and the discharge amount detection sensor 120 may calculate the ink discharge amounts through a vision sensor or the like.

The transfer device 130 may transfer the substrate including the pixel areas. The transfer device 130 may transfer the substrate for performing the printing operation using the inkjet printer 110. When the printing operation is completed, the transfer device 130 may transfer the substrate out and may transfer in a new substrate for a next printing operation. For example, the transfer device 130 may include, but is not limited thereto, a rail or a lifting device for transferring a substrate.

The controller 150 controls an overall operation of the apparatus 100 for fabricating the display panel. To this end, the controller 150 may include a printer controller 160, a sensor controller 170, a transfer controller 180, and a nozzle combination calculator 190.

The printer controller 160 may control an operation of the inkjet printer 110. The printer controller 160 may control position and movement of the plurality of nozzles during a printing time to perform the printing operation. When the controller 150 calculates positions of the nozzles based on the ink discharge amount of each of the plurality of nozzles for securing the uniformity of the pixel areas, the printer controller 160 may output a control signal to the inkjet printer 110 for moving the plurality of nozzles to the calculated positions.

The sensor controller 170 may control an operation of the discharge amount detection sensor 120. The sensor controller 170 may generate a control signal for activating the discharge amount detection sensor 120 before the printing operation is performed. The discharge amount detection sensor 120 may detect the ink discharge amounts corresponding to the plurality of nozzles, respectively, based on the control signal. Information on the detected ink discharge amounts may be provided to the controller 150.

The transfer controller 180 may control an operation of the transfer device 130. The transfer controller 180 may control the transfer device 130 to put the substrate out when the printing operation of the substrate is completed, and to receive the new substrate. The transfer controller 180 may discharge a control signal for replacing of substrates to the transfer device 130 when the printing operation is completed.

The nozzle combination calculator 190 may calculate the combination of the nozzle positions optimized for each scan of the nozzles based on the ink discharge amounts of the plurality of nozzles and shift values of the plurality of nozzles. For example, when the ink discharge amount corresponding to each of the nozzles is detected, an ink distribution, which is information on the ink discharge amounts arranged based on an arrangement order of the nozzles, is generated. Here, the ink distribution may move in parallel on a specific coordinate axis with regard to the shift values of the nozzles, which relatively move with respect to the substrate. In this case, each of the shift values indicates a movement amount of the nozzles with respect to the substrate in terms of the nozzles. In addition, the shift value indicates an amount of parallel movement in terms of the ink distribution.

For example, the nozzle combination calculator 190 may arbitrarily determine a first ink distribution corresponding to an initial nozzle position. A second ink distribution may be calculated by the nozzle combination calculator 190 to have the smallest standard deviation when summed with the first ink distribution. When the second ink distribution has the smallest standard deviation, ink uniformity of the pixel areas is greatest. The second ink distribution is used to determine a next nozzle position after the initial nozzle position. As the above-described process is repeated, the nozzle combination calculator 190 may calculate a combination of the ink distributions optimized for each of the plurality of scan times. Based on the calculated combination, the printer controller 160 may generate a control signal for adjusting the positions of the plurality of nozzles. A detailed operation of the nozzle combination calculator 190 will be described in more detail later.

The nozzle combination calculator 190 may calculate the combination of the ink distributions after the discharge amount detection sensor 120 detects the ink discharge amounts. Then, the nozzle combination calculator 190 may calculate the combination before the inkjet printer 110 performs the printing operation. The nozzle combination calculator 190 may complete the calculation within a time for the replacement of the substrate after the transfer device 130 completes the printing operation of the substrate. When optimized combinations of the plurality of nozzles are all calculated in the replacement of the substrates, a fabricating time of the display panel may be reduced.

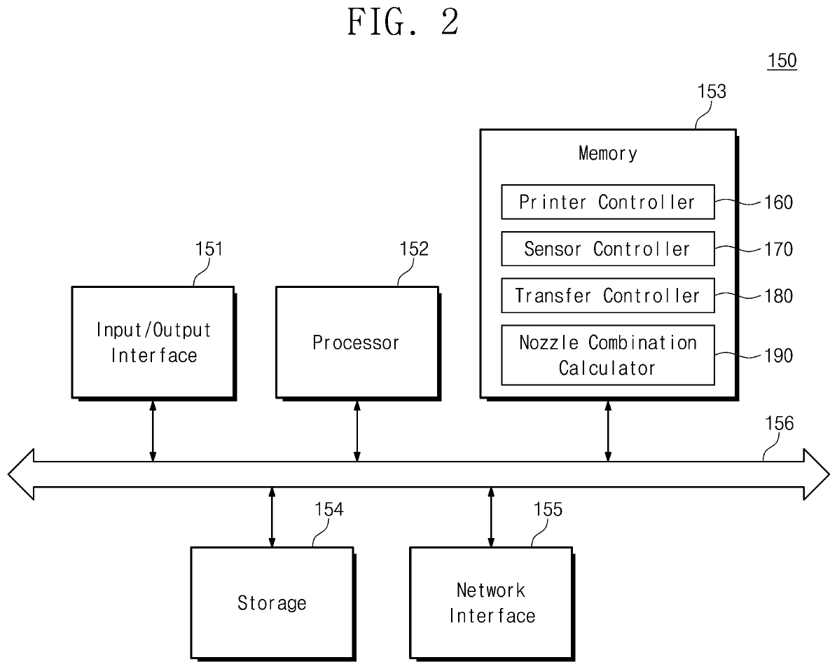

FIG. 2 is an example block diagram of a controller of FIG. 1. The controller 150 of FIG. 2 corresponds to the controller 150 of FIG. 1. Referring to FIG. 2, the controller 150 may include an input/output interface 151, a processor 152, a memory 153, storage 154, a network interface 155, and a bus 156.

The input/output interface 151 may exchange information between the inkjet printer 110, the discharge amount detection sensor 120, and the transfer device 130 of FIG. 1. For example, the input/output interface 151 may output signals for activating or controlling the inkjet printer 110, the discharge amount detection sensor 120, and the transfer device 130 to the inkjet printer 110, the discharge amount detection sensor 120, and the transfer device 130. For example, the input/output interface 151 may receive information on a printing operation status from the inkjet printer 110. The input/output interface 151 may receive information on the ink discharge amount detected from the discharge amount detection sensor 120. The input/output interface 151 may receive information on a transferring operation status from the transfer device 130.

The processor 152 may function as a central processing unit of the controller 150. The processor 152 may perform the combination calculation of the ink distributions for determining the optimized positions of the plurality of nozzles, displacement and movement of the plurality of nozzles, detection of the ink discharge amounts, and control and calculation required to determine the completion of the printing operation of the substrate and to replace the substrates. For example, the input/output interface 151 may receive information on the ink discharge amounts based on the control of processor 152. The combination of the optimized ink distributions may be calculated under the control of the processor 152. The signal to control the positions and movement of the plurality of nozzles from the calculated combination may be generated under the control of the processor 152. The processor 152 may operate using a calculation space of the memory 153 and may read files for running an operating system and executable files of applications from the storage 154.

The memory 153 may store data and processor codes, which are processed or are to be processed by the processor 152. For example, the memory 153 may store information on the ink discharge amounts provided from the input/output interface 151, information for calculating the combination of the ink distributions, information for controlling the nozzles based on the calculated combination, and information for controlling operation of the transfer device 130. The memory 153 may be used as a main memory of the controller 150. The memory 153 may include a dynamic random access memory (DRAM), a static random access memory (SRAM), a phase change RAM (PRAM), a magnetic RAM (MRAM), a ferroelectric random access memory (FeRAM), a resistive RAM (RRAM) and the like.

The printer controller 160, the sensor controller 170, the transfer controller 180, and the nozzle combination calculator 190 may be implemented in the memory 153. The printer controller 160, the sensor controller 170, the transfer controller 180 and the nozzle combination calculator 190 correspond to the printer controller 160, the sensor controller 170, the transfer controller 180, and the nozzle combination calculator 190 of FIG. 1. The printer controller 160, the sensor controller 170, the transfer controller 180, and the nozzle combination calculator 190 may be a part of an operation space of the memory 153. In this case, the printer controller 160, the sensor controller 170, the transfer controller 180, and the nozzle combination calculator 190 may be implemented in firmware or software. For example, the firmware may be stored in the storage 154 and may be loaded into the memory 153 when being executed. The processor 152 may execute the firmware loaded into the memory 153.

Unlike illustrated in FIG. 2, the printer controller 160, the sensor controller 170, the transfer controller 180, and the nozzle combination calculator 190 may be implemented with separate hardware. For example, the printer controller 160, the sensor controller 170, the transfer controller 180, and the nozzle combination calculator 190 may be implemented by a dedicated logic circuit such as a field programmable gate array (FPGA), an application specific integrated circuit (ASIC), or the like.

The storage 154 may store data generated for purpose of long-term storage by the operating system or applications, a file for running the operating system, or executable files of applications. For example, the storage 154 may store files for execution of the printer controller 160, the sensor controller 170, the transfer controller 180, and the nozzle combination calculator 190. The storage 154 may be used as an auxiliary storage device of the controller 150. The storage 154 may include a flash memory, a phase-change RAM (PRAM), a magnetic RAM (MRAM), a ferroelectric RAM (FeRAM), a resistive RAM (RRAM), and the like.

The network interface 155 may be configured to communicate with external electronic devices. For example, the network interface 155 may perform communication based on at least one of various wireless communication schemes such as long term evolution (LTE), code division multiple access (CDMA), Wi-Fi, radio frequency identification (RFID), or the like, or various wired communication schemes such as universal serial bus (USB), serial AT attachment (SATA), serial peripheral interface (SPI), inter-integrated circuit (I2C), or the like.

The bus 156 may provide a communication path between the components of the controller 150. The input/output interface 151, the processor 152, the memory 153, the storage 154, and the network interface 155 may exchange data with one another via the bus 156. The bus 156 may be configured to support various types of communication formats used in the controller 150.

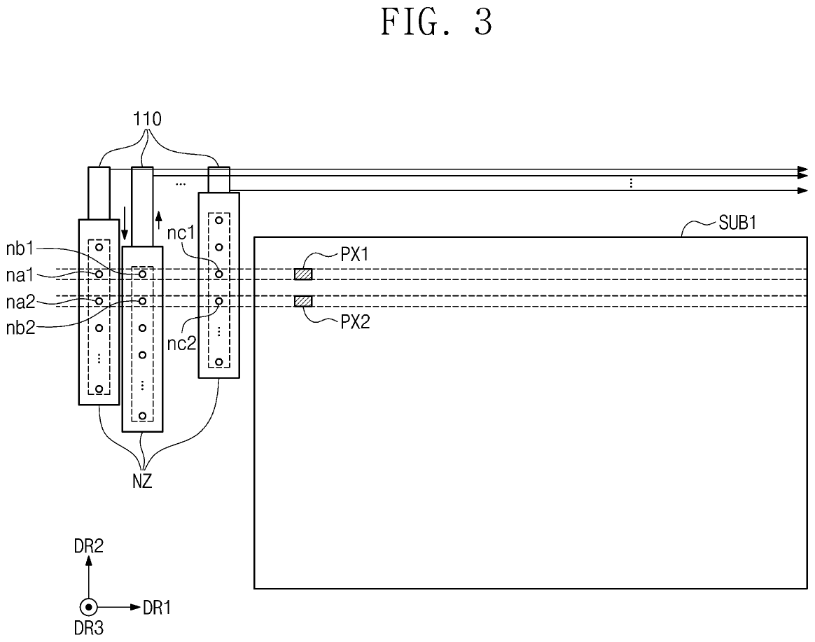

FIG. 3 is an example view of a process in which the inkjet printer of FIG. 1 performs a printing operation on a substrate. FIG. 3 illustrates a part of an inkjet printer 110, and illustratively shows a head for ejecting the ink. Referring to FIG. 3, the inkjet printer 110 includes a nozzle unit NZ for discharging the ink to a substrate SUB1, and the nozzle unit NZ includes the plurality of nozzles. The number of nozzles is not limited.

In the following description from FIG. 3, for the sake of the convenience of the description, first to third directions DR1 to DR3 are defined. The first direction DR1 is defined as a direction in which the nozzle unit NZ scans the substrate SUB1 for the printing operation. The second direction DR2 may be defined as an arrangement direction of the plurality of nozzles included in the nozzle unit NZ and may be perpendicular to the first direction DR1. The third direction DR3, which is perpendicular to the first and second directions DR1 and DR2, respectively, is defined as a direction of discharging or ejecting the ink.

The substrate SUB1 may be included in the display panel and may include, for example, a synthetic resin substrate or a glass substrate. A light blocking pattern, a color filter, a color control layer, and the like may be formed on the substrate SUB1. For an example, the light blocking pattern may be formed to divide pixels, which are formed on the substrate SUB1. FIG. 3 illustratively shows a first pixel PX1 and a second pixel PX2. The first pixel PX1 and the second pixel PX2 may provide the same color light and may provide, for example, a red light, a green light, or a blue light. According to some example embodiments, pixels providing different color lights from the first pixel PX1 and the second pixel PX2 may be formed between the first pixel PX1 and the second pixel PX2. The color control layer may be formed at the first pixel PX1 and the second pixel PX2 through the nozzle unit NZ.

A space between the plurality of nozzles may correspond to a space between the pixels providing the same color light. In an example, a distance between the first pixel PX1 and the second pixel PX2 may be a minimum distance between the pixels providing the same color light in the second direction DR2. In this case, the space between the plurality of nozzles may correspond to the distance between the first pixel PX1 and the second pixel PX2.

The nozzle unit NZ may scan substrate SUB1 several times in the first direction DR1 to discharge the ink to the effective area. The effective area may include pixel areas in which the nozzle unit NZ discharges the ink. The number of scans may be predetermined in the apparatus 100 for fabricating the display panel. For example, during a first scan time, a first nozzle na1 may provide the ink to a line (a first line) including the first pixel PX1 and a second nozzle na2 may provide the ink to a line (a second line) including the second pixel PX2. During a second scan time, a third nozzle nb1 may provide the ink to the first line, and a fourth nozzle nb2 may provide the ink to the second line. During the last scan time, a fifth nozzle nc1 may provide the ink to the first line, and a sixth nozzle nc2 may provide the ink to the second line.

The first nozzle na1 and the second nozzle na2 may be adjacent to each other, the third nozzle nb1 and the fourth nozzle nb2 may be adjacent to each other, and the fifth nozzle nc1 and the sixth nozzle nc2 may be adjacent to each other. For the sake of convenience of explanation, the first to sixth nozzles na1, na2, nb1, nb2, nc1 and nc2 are separately described, but the first nozzle na1 may be the same as at least one of the third through sixth nozzles nb1, nb2, nc1, and nc2. For example, the first nozzle na1 and the fourth nozzle nb2 may be the same nozzle with different scan times.

The first nozzle na1 and the second nozzle na2 may have the different ink discharge amounts. In this case, a volume of the ink filled in the first pixel PX1 and a volume of the ink filled in the second pixel PX2 may be different from each other during the first scan time. Furthermore, volumes of the ink filled in the pixels through the plurality of nozzles during the first scan time may be different from each other. The nozzle combination calculator 190 of FIG. 1 may calculate the optimized nozzle combination from the first scan time to the last scan time before the first scan time.

As a result of the calculation of the nozzle combination, when the third nozzle nb1 provides the ink to the first pixel PX1 and the fourth nozzle nb2 provides the ink to the second pixel PX2 during the second scan time, it may be determined that the volumes of the ink filled in the pixels are the most uniform. The nozzle unit NZ may move in the second direction DR2 such that the third nozzle nb1 scans the first pixel PX1 when the first nozzle na1 and the third nozzle nb1 are different from each other. For example, the nozzle unit NZ of FIG. 3 moves in the second direction DR2 by one nozzle space. An area (a first effective area) filled through the plurality of nozzles during the first scan time overlaps at least a part of an area (a second effective area) filled through the plurality of nozzles during the second scan time. The overlapped area of the first pixel area and the second pixel area may have an improved uniformity through the second scan time. In an example, a part of the first effective area, which is not overlapped with the second effective area, may be filled through additional scans. In this case, the nozzles for discharging the ink in the additional scans may be nozzles other than nozzles for ejecting the ink to the overlapped area during the second scan time.

When the final scan is completed, the uniformity of the entire pixels provided with the ink through the nozzle unit NZ may meet a reference range. According to some example embodiments, the reference range may be a tolerance range of a normal display panel, in which a user is not capable of recognizing characteristic differences between the pixels. In addition, the uniformity may be related to the difference in the thickness or volume of the color control layer formed by discharging the ink throughout the entire pixels. That is, one nozzle may be not exclusively charged of one pixel but the apparatus 100 for fabricating the display panel may uniformly adjust the volume of the ink filled in each of the pixels through the combination of the plurality of nozzles.

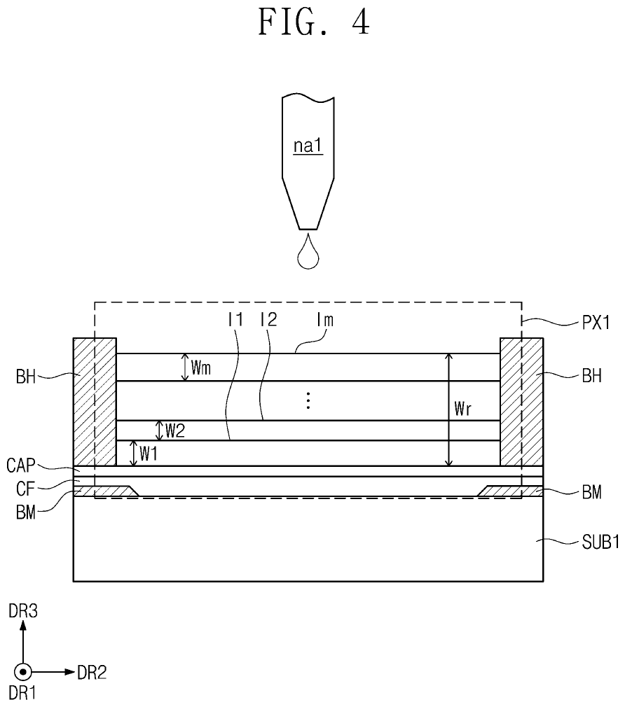

FIG. 4 is an example cross-sectional view of a pixel of FIG. 3. A pixel PX1 of FIG. 4 corresponds to the first pixel PX1 of FIG. 3. Referring to FIG. 4, the pixel PX1 may include a light blocking pattern BM, a color filter CF, a capping layer CAP, a barrier wall BH, and a color control layer in which the ink is accumulated.

The light blocking pattern BM may be positioned on the substrate SUB1. The light blocking pattern BM may set a boundary between the pixels and may prevent or reduce color mixing between the pixels. The light blocking pattern BM may include an opaque material and may block light.

The color filter CF may be located on the substrate SUB1. The color filter CF reduces reflectance of an external light. The color filter CF may transmit a light belonging to a specific wavelength range and block a light outside the specific wavelength range. The color filter CF may absorb the light outside the specific wavelength range. The color filter CF may include a pigment or a dye capable of absorbing the light outside the specific wavelength range.

The capping layer CAP may be located on the light blocking pattern BM and the color filter CF. The capping layer CAP may seal the light blocking pattern BM and the color filter CF. The capping layer CAP may include an inorganic layer. The capping layer CAP may include any one of silicon oxide, silicon nitride, or silicon oxynitride. The capping layer CAP may further include an organic layer.

The barrier wall BH may be located on the capping layer CAP and may overlap the light blocking pattern BM with respect to the third direction DR3. The barrier wall BH defines a space inside the pixel PX1. The barrier wall BH prevents or reduces instances of different color compositions being mixed through an inkjet print in a process of forming the color control layer.

The color control layer is located in an inner space defined by the barrier wall BH. In an example, the color control layer may absorb a color light generated in an organic light emitting element (OLED) and may generate a light of a different color. According to some example embodiments, the color control layer may transmit and scatter the color light. The color control layer may be formed by accumulating the ink discharged through the nozzle na1.

During the first scan time, the nozzle na1 may discharge the ink and a first ink 11 having a first thickness W1 may be filled in the inner space. During the second scan time, a nozzle which is the same as or different from the nozzle na1 may discharge the ink and a second ink 12 having a second thickness W2 may be filled in the inner space. The first thickness W1 and the second thickness W2 may be different from each other when the nozzle na1 for discharging the ink at the first scan time and the nozzle for discharging the ink at the second scan time are different from each other. During the last scan (an m-th scan time), a nozzle may discharge the ink and an m-th ink Im having an m-th thickness Wm may be filled in the inner space.

A thickness Wr of the color control layer corresponding to the sum of the first to m-th thicknesses W1 to Wm may be within the tolerable range that is, within a reference thickness, from a required thickness. In addition, a thickness of a color control layer in each of other pixels may also be within the reference thickness from a required thickness by the combination of the nozzle positions corresponding to each of the scan times. That is, the uniformity with respect to the thickness Wr of the color control layer throughout the entire pixels may be improved.

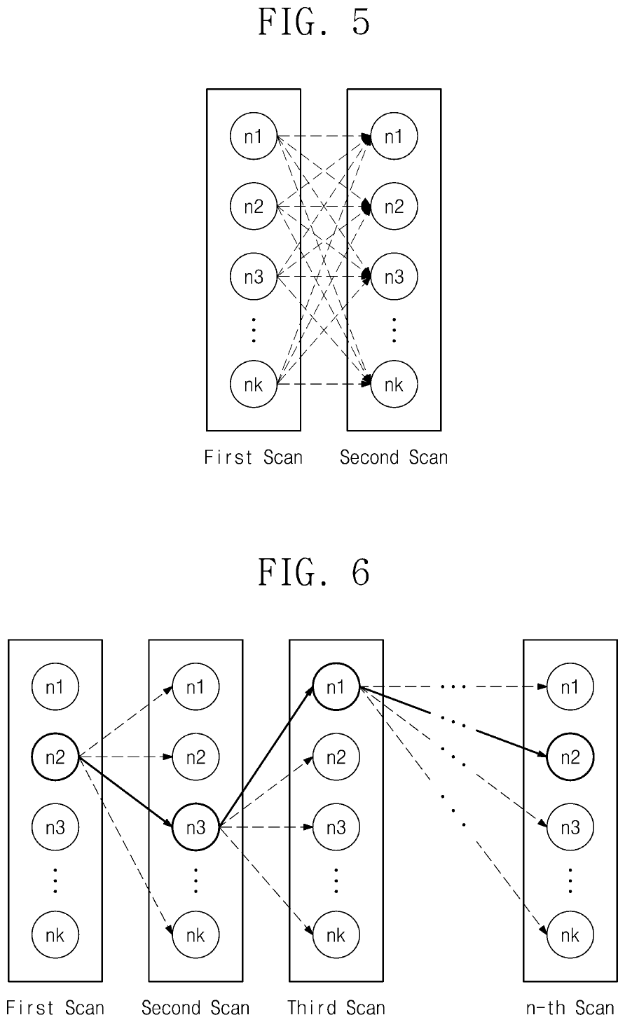

FIG. 5 is a diagram illustrating a process for calculating a combination of optimal nozzle positions for each of a plurality of scan times. Referring to FIG. 5, two scans may be performed according to some example embodiments. For example, the positions of the nozzles may be changed for each scanning operation. When the inkjet printer 110 of FIG. 1 performs two scans, the controller 150 may calculate the combination with the highest uniformity of the pixels. The number of nozzles is assumed to be k.

In terms of nozzle position control, first to k-th shift values n1 to nk may indicate the positions of the nozzles. The first shift value n1 may indicate a specific first nozzle position. Each of the second to k-th shift values n2 to nk may indicate a nozzle position shifted by a specific distance with respect to the first nozzle position. For example, when a space between adjacent nozzles is defined as a reference interval, the second shift value n2 may indicate a nozzle position shifted from the first nozzle position by the reference interval. The third shift value n3 may indicate a nozzle position shifted by twice the reference interval from the first nozzle position. The first to k-th shift values n1 to nk may indicate the relative positions of the nozzles with regard to the effective area of the substrate.

In terms of the ink discharge amounts corresponding to the nozzles, the first to k-th shift values n1 to nk may indicate arrangement order of the nozzles and distributions of the ink discharge amounts corresponding to the movement (shift) of the nozzles. The first shift value n1 may be an arrangement order of the plurality of nozzles and may indicate the distribution (dispersion) of the ink discharge amounts corresponding to the nozzles. The second shift value n2 may be an order shifted by one from the arrangement order of the nozzles (e.g., in an order of cyclic shift by one), and may indicate the distributions of the ink discharge amounts. For example, at the second shift value n2, an ink discharge amount of the first nozzle may be shifted to a position of the second nozzle and an ink discharge amount of the second nozzle may be shifted to a position of the third nozzle. Then, an ink discharge amount of the kth nozzle may be shifted to a position of the first nozzle.

Referring to FIG. 5, according to some example embodiments, the first to k-th shift values n1 to nk of the first scanning operation and the first to k-th shift values n1 to nk of the second scanning operation may be combined. That is, there are k² combinations. The sum of the ink discharge amount distributions in the first scanning operation and the ink discharge amount distributions in the second scanning operation is calculated for all the cases. As a result, one combination having the most uniform ink discharge amount distributions may be selected. The selected combination may be a combination with the smallest standard deviation.

In the case of FIG. 5, the combination having the smallest standard deviation may be selected, considering all the cases. Meanwhile, because the number of calculation may increase exponentially as the number of scans increases, the fabricating speed of the display panel may be reduced and a delay for calculation may be generated. For example, when the number of nozzles is 1280, a calculation time of the controller 150 for selecting one combination in two scanning operations exceeds 100 seconds. The above calculation may be time consuming because it is performed on a plurality of substrates per printing operation.

FIG. 6 is a view illustrating a process for calculating a combination of optimal nozzle positions according to some example embodiments of the inventive concept. Referring to FIG. 6, n scans are performed. For example, the positions of the nozzles may be changed for each scanning operation. When the inkjet printer 110 of FIG. 1 performs n scans, the controller 150 may calculate the combination of the optimized nozzle positions where the uniformity of the pixels satisfies the reference range. The number of nozzles is assumed to be k.

As described in FIG. 5, in terms of position control of the nozzles, the first to k-th shift values n1 to nk may indicate the positions of the nozzles. Further, in terms of the ink discharge amounts corresponding to the nozzles, the first to k-th shift values n1 to nk may indicate the arrangement order of the nozzles and the ink discharge amount distributions corresponding to the movement (shift) of the nozzles.

Referring to FIG. 6, unlike FIG. 5, the first to k-th shift values n1 to nk of each scanning operation are not all combined. Instead, the controller 150 or the nozzle combination calculator 190 of FIG. 1 may select a combination having the highest uniformity for each scanning operation. For example, in the first scanning operation, any one value (e.g., the second shift value n2) of the first to k-th shift values n1 to nk is selected. In the second scanning operation, the ink discharge amount distribution corresponding to the second shift value n2 and the ink discharge amount distributions respectively corresponding to the first to k-th shift values n1 to nk are combined. For example, summed distributions may be generated by summing up the ink discharge amount distribution corresponding to the second shift value n2 and the ink discharge amount distributions corresponding to the first to k-th shift values n1 to nk. A distribution (e.g., the third shift value n3) having the smallest standard deviation among the summed distributions may be selected. That is, a value having the highest uniformity may be selected based on the second shift value n2.

Similarly, in the third scanning operation, a value (e.g., the first shift value n1) that makes the highest uniformity may be selected on the condition that the second shift value n2 and the third shift value n3 are previously selected. When the shift value corresponding to the first scanning operation is arbitrarily selected, a calculation for selecting the value of the subsequent scanning operation based on the previously determined shift value(s) may be repeated n−1 times. That is, k*(n−1) operations may be performed.

In the case of FIG. 6, although the number of all cases is not taken into consideration, the above calculation may select the combination with the highest uniformity for each scanning operation to draw a result that the uniformity of the pixels meets the reference range. In addition, because the combination result in FIG. 6 may have a remarkably lower computational complexity as compared with FIG. 5, the combination may be determined at a high speed. For example, when the number of nozzles is 1280, the calculation time of the controller 150 for selecting one combination in eight scanning operations is only about 0.1 second. Compared with FIG. 5, a method of FIG. 6 may ensure the uniformity of the reference range and may output the result at a high speed, while calculating the nozzle movement more times.

A combination calculation process of FIG. 6 may be performed during the replacement time of the substrates. When the printing operation for one substrate is completed, the transfer device 130 of FIG. 1 may ship the substrate on which the printing operation has been completed and may receive a new substrate. The above transferring operation may take about 30 seconds. The calculation method of FIG. 5 is difficult to perform during the transferring operation, but the calculation method of FIG. 6 may be performed in real time within the transferring operation. Therefore, the fabricating speed of the display panel may be improved and quality of the display panel may be assured.

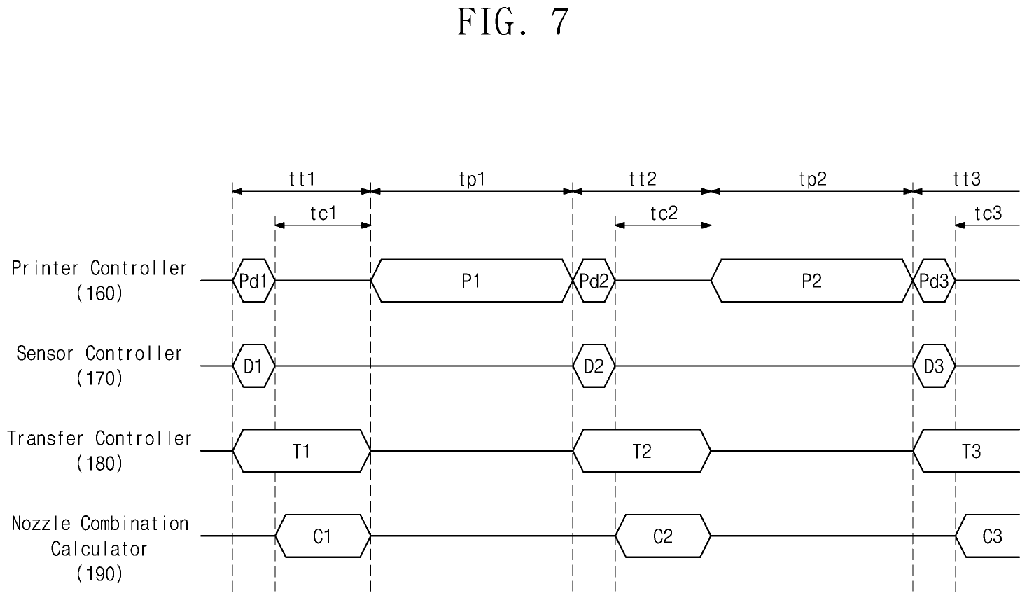

FIG. 7 is an example timing chart of a method of fabricating a display panel using an apparatus for fabricating the display panel of FIG. 1. The method of fabricating the display panel of FIG. 7 may be controlled and performed through the printer controller 160, the sensor controller 170, the transfer controller 180, and the nozzle combination calculator 190 of FIG. 1.

During a first replacement time tt1, the apparatus 100 for fabricating the display panel of FIG. 1 may detect the ink discharge amount of each of the nozzles of the inkjet printer 110, may calculate an optimized nozzle combination (a combination of the ink distributions), and may perform a transferring operation for the printing operation of the substrate. The transfer controller 180 may control a first transferring operation T1 of the transfer device 130 for entering the first substrate into the apparatus 100 for fabricating the display panel. The transfer device 130 may transfer the first substrate under the control of the transfer controller 180.

For the printing operation of the first substrate, the ink discharge amount of each of the nozzles may be detected in advance. The printer controller 160 may control a first ink discharging operation Pd1 such that the inkjet printer 110 discharges the ink. The sensor controller 170 may control a first detecting operation D1 to detect the discharged ink discharge amount. The discharge amount detection sensor 120 may provide information on the ink discharge amount of each of the plurality of nozzles to the controller 150.

The nozzle combination calculator 190 may perform a first calculating operation C1 for the printing operation of the first substrate based on the information on the ink discharge amount. As illustrated in FIG. 6, the nozzle combination calculator 190 may arbitrarily select one distribution of the plurality of ink discharge amount distributions and may repeatedly select the ink discharge amount distribution having the smallest standard deviation with regard to the selected the ink discharge distribution for the number of the scanning operations. The first calculating operation C1 may be performed within a first reference time tc1 and the first reference time tc1 may be less than or equal to the first replacement time tt1. As described above, the calculation time of FIG. 6 may be capable of being performed within the first reference time tc1.

During a first printing time tp1, the printer controller 160 may control a first printing operation P1 for discharging the ink to the pixel area of the first substrate. The printer controller 160 may control the positions of the nozzles based on the result of the combination of the nozzle positions calculated from the nozzle combination calculator 190. The first printing time tp1 may include a plurality of scan times and the printer controller 160 may control the determined positions of the nozzles for the plurality of scan times.

After completion of the first printing operation P1, the transfer controller 180 may control a second transferring operation T2 in which the first substrate is shipped and a new second substrate is entered during a second replacement time tt2. In this case, the printer controller 160 may control a second ink discharging operation Pd2 for detecting the ink discharge amounts of the nozzles and may control a second detecting operation D2 for detecting the discharged ink discharge amounts. Further, the nozzle combination calculator 190 may perform a second calculating operation C2 for the printing operation of the second substrate within a second reference time tc2 based on information on the ink discharge amounts, which are newly detected.

Similarly, during the second printing time tp2, the printer controller 160 may control a second printing operation P2 for discharging ink to the pixel area of the second substrate. Then, during a third replacement time tt3, a third transferring operation T3, a third ink discharging operation Pd3, a third detecting operation D3, and a third calculating operation C3 may be performed. That is, the replacement time of the substrates may be used for calculating the nozzle combination to improve both the fabricating speed of the display panel and the quality of the display panel.

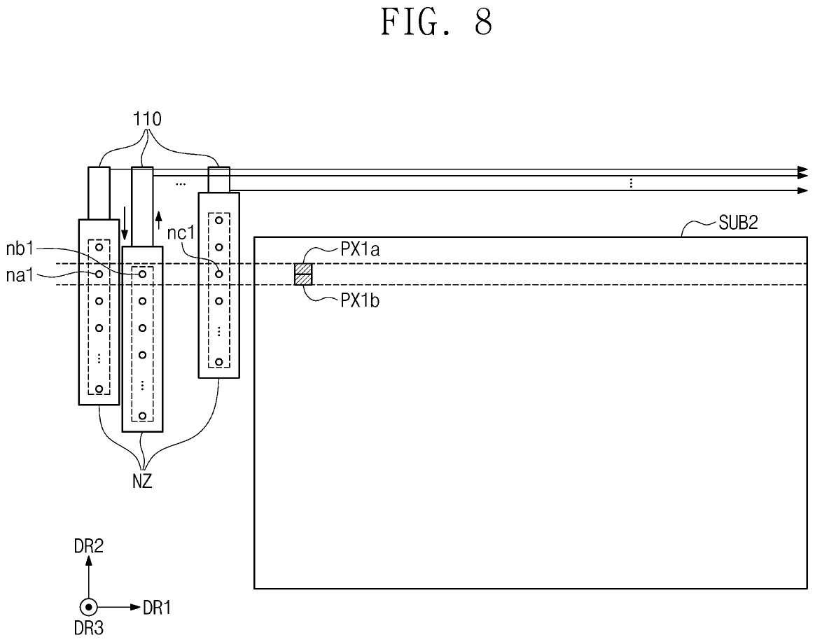

FIG. 8 is an example view illustrating a process in which an inkjet printer of FIG. 1 performs a printing operation on a substrate. Referring to FIG. 8, the inkjet printer 110 includes the nozzle unit NZ for discharging the ink to a substrate SUB2 and the nozzle unit NZ includes the plurality of nozzles, as shown in FIG. 3. The number of nozzles is not limited.

The substrate SUB 2 is included in the display panel. Unlike the substrate SUB1 of FIG. 3, the first and second pixels PX1a and PX1b that provide the same color light may be merged with each other. As a result, a sum of widths of the first and second pixels PX1a and PX1b may be wider than first pixel PX1 or the second pixel PX2 in FIG. 3. The barrier wall BH described in FIG. 4 may define a space inside the first and second pixels PX1a and PX1b. That is, the first and second pixels PX1a and PX1b may not be separated from each other by the barrier wall BH.

The merged first and second pixels PX1a and PX1b may receive the ink through one nozzle at a scan. For example, the first nozzle na1 may provide the ink to the first and second pixels PX1a and PX1b during the first scan time, the second nozzle nb1 may provide the ink to the first and second pixels PX1a and PX1b during the second scan time, and the third nozzle nc1 may provide the ink to the first and second pixels PX1a and PX1b during the last scan time. When the amount of the ink that the nozzle unit NZ discharges during one scan is the same as that of the nozzle unit NZ of FIG. 3, the nozzle unit NZ may perform double scanning operations as compared with the nozzle unit NZ of FIG. 3.

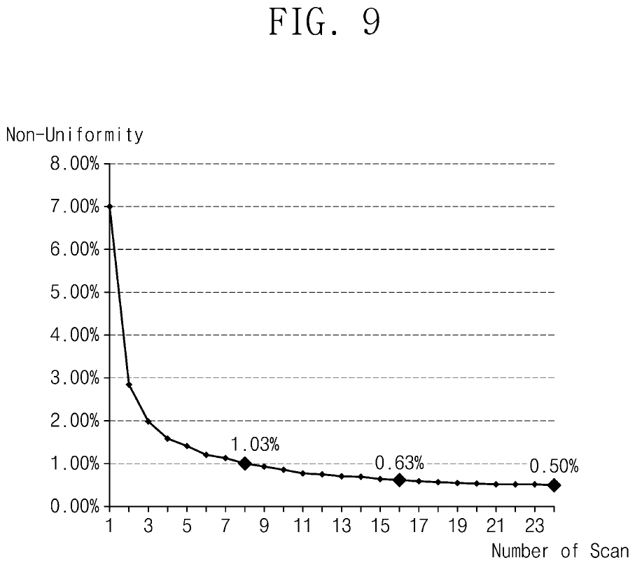

FIG. 9 is a graph illustrating non-uniformity depending on the number of scans of nozzles. Referring to FIG. 9, a horizontal axis is defined as the number of scans of the plurality of nozzles and a vertical axis is defined as the non-uniformity of the pixels. The non-uniformity is an index indicating a difference in the amount of the ink filled in each of the plurality of pixels by the inkjet printer 110 of FIG. 1. That is, the non-uniformity becomes larger as the difference in the ink amount accumulated in each of the plurality of pixels is large and irregular.

The graph of FIG. 9 is a graph when the positions of the nozzles are combined using the nozzle position combination method of FIG. 6. That is, the optimized nozzle positions for each of the scanning operations are determined by the calculation method of FIG. 6.

Referring to FIG. 9, when the number of scans is one, that is, when the scan is performed without a combination of the nozzles, the non-uniformity may be about 7%. This is because the ink discharge amounts are different from each other depending on the tolerance of each of the plurality of nozzles. As the number of scans increases, the non-uniformity of the pixels decreases. That is, the amount of the ink filled in each of the pixels may become uniform. When the number of scans is eight, for example, when one nozzle discharges the ink to one pixel as shown in FIG. 3, the non-uniformity may be 1.03%. When the number of scans is 16, for example, as shown in FIG. 8, when one nozzle discharges the ink to the area where two pixels are merged, the non-uniformity may be 0.63%.

That is, when there are merged pixels to increase the number of scans, the efficiency of the calculation method according to some example embodiments of the inventive concept may be increased. In this case, the calculation time may be double times as compared to when the number of scans is eight. Meanwhile, as described with reference to FIG. 6, the increase in the calculation time twice (0.2 second, which is the double of about 0.1 second) is shorter than substrate replacement time in about 30 seconds, and thus the fabricating speed of the display panel may not be affected.

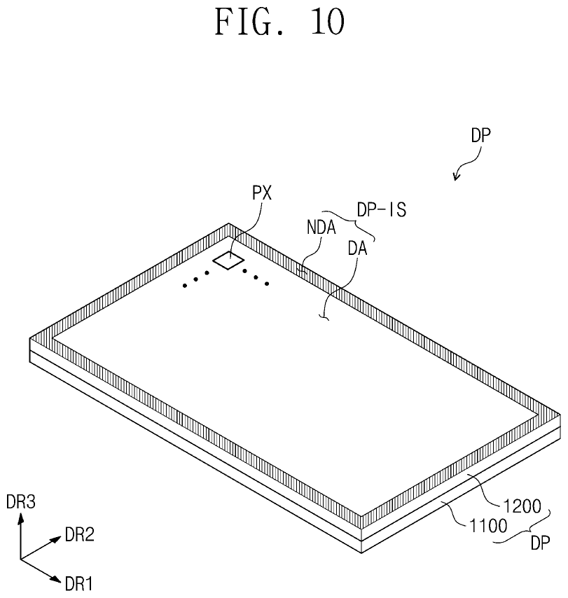

FIG. 10 is an example perspective view of a display panel manufactured in accordance to some example embodiments of the inventive concept. Referring to FIG. 10, a display panel DP may include any one of a liquid crystal display panel, an electrophoretic display panel, a microelectromechanical system (MEMS) display panel, and an electrowetting display panel, and an organic light emitting display panel, and is not particularly limited.

The display panel DP may include a first display substrate 1100 (or a lower display substrate) and a second display substrate 1200 (or an upper display substrate), which faces and spaced apart from the first display substrate 1100. The first display substrate 1100 corresponds to one of the substrates SUB1 and SUB2, which is described in FIGS. 3 and 8, on which the ink is printed. The second display substrate 1200 may include a circuit element, a display element such as a light emitting element, and the like for driving the display panel DP.

A specific cell gap may be formed between the first display substrate 1100 and the second display substrate 1200. The cell gap may be maintained by a sealant that couples the first display substrate 1100 to the second display substrate 1200. A gradation display layer for generating an image may be located between the first display substrate 1100 and the second display substrate 1200. The gradation display layer may include a liquid crystal layer, an organic light emitting layer, and an electrophoretic layer depending on types of the display panel.

The display panel DP may display an image through a display surface DP-IS. The display surface DP-IS is parallel to a plane defined by the first direction DR1 and the second direction DR2. The display surface DP-IS may include a display area DA and a non-display area NDA. The pixel PX is arranged in the display area DA and the pixel PX is not arranged in the non-display area NDA. The non-display area NDA is defined along a rim of the display surface DP-IS. The display area DA may be surrounded by the non-display area NDA.

According to some example embodiments of the inventive concept, the display panel DP having the planar display surface DP-IS is shown, but embodiments according to the inventive concept are not limited thereto. The display panel DP may include a curved display surface or a stereoscopic display surface. The stereoscopic display surface may include a plurality of display areas indicating different directions.

According to some example embodiments, the positions of the nozzles of the inkjet printer for each of the scanning operations may be adjusted in consideration of the uniformity of the pixels.

Further, according to some example embodiments, the number of operations for calculating the positions of the optimized nozzles may be reduced. Thus, the positions of the nozzles for all the scanning operations may be determined during the replacement of substrates and the speed of the inkjet printing operation may be increased.

The electronic or electric devices and/or any other relevant devices or components according to embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the exemplary embodiments of the present invention.

While the inventive concept has been described with reference to some example embodiments thereof, it will be apparent to those of ordinary skill in the art that various changes and modifications may be made thereto without departing from the spirit and scope of the inventive concept as set forth in the following claims and their equivalents.

Therefore, the technical scope of the inventive concept should not be limited to the contents described in the detailed description of the specification, but should be defined by the claims and their equivalents.

What is claimed is:

1. A device for fabricating a display panel, the device comprising:
an inkjet printer including a plurality of nozzles configured to discharge an ink to effective areas of the display panel for each of a plurality of scan times;
a discharge amount detection sensor configured to detect ink discharge amounts corresponding to the plurality of nozzles, respectively; and
a controller configured to:
generate a plurality of ink distributions based on shift values of the plurality of nozzles for the effective areas at each of the scan times and the ink discharge amounts;
select a first ink distribution discharging the ink to a first effective area during a first scan time; and
select a second ink distribution discharging the ink to a second effective area based on the first ink distribution during a second scan time after the first scan time.

2. The device of claim 1, wherein the controller is further configured to:
generate a plurality of summed distributions generated by summing the first ink distribution with each of the plurality of ink distributions; and
select an ink distribution corresponding to a summed distribution having a smallest standard deviation among the plurality of summed distributions as the second ink distribution.

3. The device of claim 2, wherein the second effective area is shifted from the first effective area based on a change in the second ink distribution with regard to the first ink distribution.

4. The device of claim 1, wherein a number of the plurality of ink distributions depends on a number of the plurality of nozzles.

5. The device of claim 1, wherein the controller is further configured to:
arrange the ink discharge amounts to correspond to an arrangement order of the plurality of nozzles; and
cyclically shift the arranged ink discharge amounts based on the arrangement order to generate the plurality of ink distributions.

6. The device of claim 1, wherein the controller is further configured to select a third ink distribution discharging the ink to a third effective area based on the first and second ink distributions during a third scan time after the second scan time.

7. The device of claim 1, wherein the plurality of nozzles move along a first direction during the first and second scan times and each of the plurality of nozzles is arranged in a second direction intersecting with the first direction.

8. The device of claim 7, wherein the plurality of nozzles are on the first effective area based on the first ink distribution during the first scan time and are shifted to the second direction to be on the second effective area based on the second ink distribution.

9. The device of claim 1, wherein the first and second effective areas are overlapped with each other to form an overlapping area, which includes first and second pixel areas, and
wherein a first nozzle of the plurality of nozzles is configured to discharge the ink in the first pixel area based on the first ink distribution during the first scan time, a second nozzle of the plurality of nozzles is configured to discharge the ink in the second pixel area based on the first ink distribution during the first scan time, a third nozzle of the plurality of nozzles is configured to discharge the ink in the first pixel area based on the second ink distribution during the second scan time, and a fourth nozzle of the plurality of nozzles is configured to discharge the ink to the second pixel area based on the second ink distribution during the second scan time.

10. The device of claim 9, wherein a difference between a first thickness of the ink accumulated in the first pixel area and a second thickness of the ink accumulated in the second pixel area is smaller than a reference thickness.

11. The device of claim 1, wherein the inkjet printer is further configured to:
discharge the ink to the first effective area based on the first ink distribution during the first scan time;
discharge the ink to the second effective area based on the second ink distribution during the second scan time; and
discharge the ink to a third effective area, which does not overlap with the second effective area or the first effective area, based on the second ink distribution during a third scan time after the second scan time.

12. The device of claim 1, wherein the controller is further configured to select the first and second ink distributions during a reference time before the first scan time.

13. The device of claim 12, wherein the reference time is shorter than 30 seconds.

14. A device for fabricating a display panel, the device comprising:
an inkjet printer including a plurality of nozzles which are configured to discharge an ink to a first substrate during a first printing time and then discharge the ink to a second substrate during a second printing time which includes a plurality of scan times;
a discharge amount detection sensor configured to detect ink discharge amounts corresponding to the plurality of nozzles, respectively; and
a controller configured to calculate a combination of ink distributions in which the inkjet printer discharges the ink to the second substrate for each of the plurality of scan times based on the ink discharge amounts and a plurality of shift values of the plurality of nozzles for effective areas of the second substrate within a reference time for replacing the first substrate with the second substrate between the first printing time and the second printing time.

15. The device of claim 14, wherein the controller is further configured to:
select a first ink distribution corresponding to an initial scan time of the plurality of scan times; and
calculate the combination based on the first ink distribution.

16. The device of claim 15, wherein the controller is further configured to:
calculate the ink distributions corresponding to a number of the plurality of nozzles based on the ink discharge amounts and the shift values; and
determine any one of the ink distributions as the first ink distribution.

17. The device of claim 15, wherein the controller is further configured to:
calculate the ink distributions corresponding to a number of nozzles based on the ink discharge amounts and the shift values; and
select an ink distribution having a smallest standard deviation when each of the ink distributions and the first ink distribution are summed up, to determine the combination.

18. A method of fabricating a display panel, the method comprising:
detecting ink discharge amounts corresponding to a plurality of nozzles, respectively;
forming a plurality of ink distributions corresponding to shift values of the plurality of nozzles based on the ink discharge amounts;
selecting a first ink distribution of the plurality of ink distributions;
selecting a second ink distribution corresponding to a result having a smallest standard deviation among results obtained by summing the first ink distribution with the plurality of ink distributions;
discharging ink to a first area of a substrate based on the first ink distribution; and
discharging the ink to a second area of the substrate, which is at least partially overlapped with the first area, based on the second ink distribution.

19. The method of claim 18, further comprising:
selecting a third ink distribution corresponding to a result having the smallest standard deviation among results obtained by summing the first and second ink distributions with the plurality of ink distributions; and
discharging the ink to a third area, which is at least partially overlapped with the first area or the second area, based on the third ink distribution.

20. The method of claim 18, wherein the first ink distribution and the second ink distribution are selected within a reference time, and
wherein after the reference time, the ink is discharged to the first and second areas.
